(19) United States
(12) Patent Application Publication
(10) Pub. No.: US 2008/0052594 A1
(43) Pub. Date: Feb. 28, 2008

(54) Method and system for replica group-shuffled iterative decoding of quasi-cyclic low-density parity check codes

(76) Inventors: Jonathan S. Yedidia, Cambridge, MA (US); Marc P. Fossorier, Honolulu, HI (US); Jeffrey S. Proctor, Sudbury, MA (US); Wenyi Jin, Cupertino, CA (US); Yige Wang, Honolulu, HI (US)

Correspondence Address: MITSUBISHI ELECTRIC RESEARCH LABORATORIES, INC., 201 BROADWAY, 8TH FLOOR, CAMBRIDGE, MA, 02139, US

(21) Appl. No.: 11/494,921

(22) Filed: Jul. 28, 2006

(51) Int. Cl. H03M 13/00

(52) U.S. Cl. 714/758

(57) ABSTRACT

A block of symbols are decoded using iterative belief propagation. A set of belief registers store beliefs that a corresponding symbol in the block has a certain value. Check processors determine output check-to-bit messages from input bit-to-check messages by message-update rules. Link processors connect the set of belief registers to the check processors. Each link processor has an associated message register. Messages and beliefs are passed between the set of belief registers and the check processors via the link processors for a predetermined number of iterations while updating the beliefs to decode the block of symbols based on the beliefs at termination.

### RELATED APPLICATION

This is a Continuation-in-Part Application of United States Patent Application 20060161830, by Yedidia; Jonathan S. et al. filed Jul. 20, 2006, “Combined-replica group-shuffled iterative decoding for error-correcting codes.”

### FIELD OF THE INVENTION

The present invention relates generally to decoding error-correcting codes, and more specifically to iteratively decoding error-correcting codes such as turbo-codes, and low density parity check (LDPC) codes.

### BACKGROUND OF THE INVENTION

Error-Correcting Codes

A fundamental problem in the field of data storage and communication is the development of practical decoding methods for error-correcting codes.

One very important class of error-correcting codes is the class of linear block error-correcting codes. Unless specified otherwise, any reference to a “code” in the following description should be understood to refer to a linear block error-correcting code.

The basic idea behind these codes is to encode a block of k information symbols using a block of N symbols, where N>k. The additional N-k bits are used to correct corrupted signals when they are received over a noisy channel or retrieved from faulty storage media.

A block of N symbols that satisfies all the constraints of the code is called a “code-word,” and the corresponding block of k information symbols is called an “information block.” The symbols are assumed to be drawn from a q-ary alphabet.

An important special case is when q=2. In this case, the code is called a “binary” code. In the examples given in this description, binary codes are assumed, although the generalization of the decoding methods described herein to q-ary codes with q>2 is straightforward. Binary codes are the most important codes used in practice.

FIG. 1 shows a conventional “channel coding” 100 with a linear block error-correcting code. A source 110 produces an information block 101 of k symbols u[a]. The information block is passed to an encoder 120 of the error-correcting code. The encoder produces a code-word x[n] containing N symbols 102.

The code-word 102 is then transmitted through a channel 130, where the code-word is possibly corrupted into a signal y[n] 103. The corrupted signal y[n] 103 is then passed to a decoder 140, which attempts to output a reconstruction 104 z[n] of the code-word x[n] 102.

Code Parameters

A binary linear block code is defined by a set of 2^{k} possible code-words having a block length N. The parameter k is sometimes called the “dimension” of the code. Codes are normally much more effective when N and k are large. However, as the size of the parameters N and k increases, so does the difficulty of decoding corrupted messages.

The Hamming distance between two code-words is defined as the number of symbols that differ in two words. The distance d of a code is defined as the minimum Hamming distance between all pairs of code-words in the code. Codes with a larger value of d have a better error-correcting capability. Codes with parameters N and k are referred to as [N,k] codes. If the distance d is also known, then the codes are referred to as [N, k, d] codes.

Code Parity Check Matrix Representations

A linear code can be represented by a parity check matrix. The parity check matrix representing a binary [N,k] code is a matrix of zeros and ones, with M rows and N columns. The N columns of the parity check matrix correspond to the N symbols of the code, and M to the number of check bits. The number of linearly independent rows in the matrix is N-k.

Each row of the parity check matrix represents a parity check constraint. The symbols involved in the constraint represented by a particular row correspond to the columns that have a non-zero symbol in that row. The parity check constraint enforces the weighted sum modulo-2 of those symbols to be equal to zero. For example, for a binary code, the parity check matrix

$$H = [ \begin{matrix}1 & 1 & 1 & 0 & 1 & 0 & 0 \\ 0 & 1 & 1 & 1 & 0 & 1 & 0 \\ 0 & 0 & 1 & 1 & 1 & 0 & 1\end{matrix} ] \qquad ( 4 )$$

represents the three constraints

x[1]+x[2]+x[3]+x[5]=0 (5)

x[2]+x[3]+x[4]+x[6]=0 (6)

x[3]+x[4]+x[5]+x[7]=0, (7)

where x[n] is the value of the n^{th} bit, and the addition of binary symbols is done using the rules of modulo-2 arithmetic, such that 0+0=1+1=0, and 0+1=1+0=1.

Error-Correcting Code Decoders

The task of a decoder for an error-correcting code is to accept the received signal after the transmitted code-word has been corrupted in a channel, and try to reconstruct the transmitted code-word. The optimal decoder, in terms of minimizing the number of code-word decoding failures, outputs the most likely code-word given the received signal. The optimal decoder is known as a “maximum likelihood” decoder. Even a maximum likelihood decoder will sometimes make a decoding error and output a code-word that is not the transmitted code-word if the noise in the channel is sufficiently great.

Another type of decoder, which is optimal in terms of minimizing the symbol error rate rather than the word error rate, is an “exact-symbol” decoder. This name is actually not conventional, but is used here because there is no universally agreed-upon name for such decoders. The exact-symbol decoder outputs, for each symbol in the code, the exact probability that the symbol takes on its various possible values, e.g., 0 or 1 for a binary code.

Iterative Decoders

In practice, maximum likelihood or exact-symbol decoders can only be constructed for special classes of error-correcting codes. There has been a great deal of interest in non-optimal, approximate decoders based on iterative methods. One of these iterative decoding methods is called “belief propagation” (BP). Although he did not call it by that name, R. Gallager first described a BP decoding method for low-density parity check (LDPC) codes in 1963.

Turbo Codes

In 1993, similar iterative methods were shown to perform very well for a new class of codes known as “turbo-codes.” The success of turbo-codes was partially responsible for greatly renewed interest in LDPC codes and iterative decoding methods. There has been a considerable amount of recent work to improve the performance of iterative decoding methods for both turbo-codes and LDPC codes, and other related codes such as “turbo product codes” and “repeat-accumulate codes.” For example a special issue of the IEEE Communications Magazine was devoted to this work in August 2003. For an overview, see C. Berrou, “The Ten-Year-Old Turbo Codes are entering into Service,” IEEE Communications Magazine, vol. 41, pp. 110-117, August 2003 and T. Richardson and R. Urbanke, “The Renaissance of Gallager's Low-Density Parity Check Codes,” IEEE Communications Magazine, vol. 41, pp. 126-131, August 2003.

Many turbo-codes and LDPC codes are constructed using random constructions. For example, Gallager's original binary LDPC codes are defined in terms of a parity check matrix, which consists only of 0's and 1's, where a small number of 1's are placed randomly within the matrix according to a pre-defined probability distribution. However, iterative decoders have also been successfully applied to codes that are defined by regular constructions, like codes defined by finite geometries, see Y. Kou, S. Lin, and M. Fossorier, “Low Density Parity Check Codes Based on Finite Geometries: A Rediscovery and More,” IEEE Transactions on Information Theory, vol. 47, pp. 2711-2736, November, 2001. In general, iterative decoders work well for codes with a parity check matrix that has a relatively small number of non-zero entries, whether that parity check matrix has a random or regular construction.

FIG. 2 shows a prior art system 200 with a decoder of an LDPC code based on BP. The system processes the received symbols iteratively to improve the reliability of each symbol based on the constraints enforced by the parity check matrix that specifies the code.

In a first iteration, the BP decoder only uses channel evidence 201 as input, and generates soft output messages 202 from each symbol to the parity check constraints involving that symbol. This step of sending messages from the symbols to the constraints is sometimes called the “vertical” step 210. Then, the messages from the symbols are processed at the neighboring constraints to feed back new messages 203 to the symbols. This step is sometimes called the “horizontal” step 220. The decoding iteration process continues to alternate between vertical and horizontal steps until a certain termination condition 204 is satisfied. At that point, hard decisions 205 are made for each symbol based on the output reliability measures for symbols from the last decoding iteration.

The precise form of the message update rules, and the meaning of the messages, varies according to the particular variant of the BP method that is used. Two particularly popular message-update rules are the “sum-product” rules and the “min-sum” rules. These prior-art message update rules are very well known, and approximations to these message update rules also have proven to work well in practice. Other prior-art message-update rules include rules using quantized messages, and normalized min-sum rules. These message-update rules try to achieve good performance using less computational resources.

In some variants of the BP method, the messages represent the probability, specifically, the log-likelihood that a bit is either a 0 or a 1. For more background material on the BP method and its application to error-correcting codes, see F. R. Kschischang, B. J. Frey, and H.-A. Loeliger, “Factor Graphs and the Sum-Product Algorithm,” IEEE Transactions on Information Theory, vol 47, pp. 498-519, February 2001.

It is sometimes useful to think of the messages from symbols to check constraints (also called “bit-to-check messages”) as being the “fundamental” independent messages that are tracked in BP decoding, and the messages from check constraints to symbols (also called “check-to-bit messages”) as being dependent messages that are defined in terms of the messages from symbols to constraints. Alternatively, one can view the messages from constraints to symbols as being the “independent” messages, and the messages from symbols to constraints as being “dependent” messages defined in terms of the messages from constraints to symbols.

Bit-Flipping Decoders

Bit-flipping (BF) decoders are iterative decoders that work similarly to BP decoders. These decoders are somewhat simpler. Bit-flipping decoders for LDPC codes also have a long history, and were also suggested by Gallager in the early 1960's when he introduced LDPC codes. In a bit-flipping decoder, each code-word bit is initially assigned to be a 0 or a 1 based on the channel output. Then, at each iteration, the syndrome for each parity check is computed. The syndrome for a parity check is 0 if the parity check is satisfied, and 1 if it is unsatisfied. Then, for each bit, the syndromes of all the parity checks that contain that bit are checked. If a number of those parity checks greater than a pre-defined threshold are unsatisfied, then the corresponding bit is flipped. The iterations continue until all the parity checks are satisfied or a predetermined maximum number of iterations is reached.

Turbo-Codes

A turbo-code is a concatenation of two smaller codes that can be decoded using exact-symbol decoders, see C. Berrou and A. Glavieux, “Near-Optimum Error-Correcting Coding and Decoding: Turbo-codes,” IEEE Transactions in Communications, vol. 44, pp. 1261-1271, October 1996. Convolutional codes are typically used for the smaller codes, and the exact-symbol decoders are usually based on the BCJR decoding method; see L. Bahl, J. Cocke, F. Jelinek, and J. Raviv, “Optimal Decoding of Linear Codes for Minimizing Symbol Error Rate,” IEEE Transactions on Information Theory, pp. 284-287, March 1974 for a detailed description of the BCJR decoding method. Some of the code-word symbols in a turbo-code have constraints enforced by both codes. These symbols are called “shared symbols.” A conventional turbo-code decoder functions by alternately decoding the codes using their exact-symbol decoders, and utilizing the output log-likelihoods for the shared symbols determined by one exact-symbol decoder as inputs for the shared symbols in the other exact-symbol decoder.

The structure of a turbo-code constructed using two systematic convolutional codes 301 and 302 is shown schematically in FIG. 3. In this turbo-code, the shared symbols are the information bits for each of the convolutional codes.

The simplest turbo-decoders operate in a serial mode. In this mode, one of the BCJR decoders receives as input the channel information, and then outputs a set of log-likelihood values for each of the shared information bits. Together with the channel information, these log-likelihood values are used as input for the other BCJR decoder, which sends back its output to the first decoder and then the cycle continues.

Turbo Product Codes

A turbo product code (TPC) is a type of product code wherein each constituent code can be decoded using an exact-symbol decoder. Product codes are well-known prior-art codes. To construct a product code from a [N₁, k₁, d₁] code and a [N₂, k₂, d₂] code, one arranges the code-word symbols in a N₁ by N₂ rectangle. Each symbol belongs to two codes—one a [N₁, k₁, d₁] “vertical” code constructed using the other symbols in the same column, and the other a [N₂, k₂, d₂] “horizontal” code constructed using the other symbols in the same row. The overall product code has parameters [N₁N₂, k₁k₂, d₁d₂].

The TPC is decoded using the exact-symbol decoders of the constituent codes. The horizontal codes and vertical codes are alternately decoded using their exact-symbol decoders, and the output log-likelihoods given by the horizontal codes are used as input log-likelihoods for the vertical codes, and vice-versa. This method of decoding turbo product codes is called “serial-mode decoding.”

Other Iterative Decoders

There are many other codes that can successfully be decoded using iterative decoding methods. Those codes are well-known in the literature and there are too many of them to describe them all in detail. Some of the most notable of those codes are the irregular LDPC codes, see M. A. Shokrollahi, D. A. Spielman, M. G. Luby, and M. Mitzenmacher, “Improved Low-Density Parity Check Codes Using Irregular Graphs,” IEEE Trans. Information Theory, vol. 47, pp. 585-598 February 2001; the repeat-accumulate codes, see D. Divsalar, H. Jin, and R. J. McEliece, “Coding Theorems for ‘Turbo-like’ Codes,” Proc. 36^{th} Allerton Conference on Communication, Control, and Computing, pp. 201-210, September, 1998; the LT codes, see M. Luby, “LT Codes,” Proc. Of the 43 Annual IEEE Symposium on Foundations of Computer Science, pp. 271-282, November 2002; and the Raptor codes, see A. Shokrollahi, “Raptor Codes,” Proceedings of the IEEE International Symposium on Information Theory, p. 36, July 2004.

Methods to Speed Up Iterative Decoders

BP and BF decoders for LDPC codes, decoders for turbo codes, and decoders for turbo product codes are all examples of iterative decoders that have proven useful in practical systems. A very important issue for all those iterative decoders is the speed of convergence of the decoder. It is desired that the number of iterations required before finding a code-word is as small as possible. A smaller number of iterations results in faster decoding, which is a desired feature for error-correction systems.

For turbo-codes, faster convergence can be obtained by operating the turbo-decoder in parallel mode, see D. Divsalar and F. Pollara, “Multiple Turbo Codes for Deep-Space Communications,” JPL TDA Progress Report, pp. 71-78, May 1995. In that mode, both BCJR decoders simultaneously receive as input the channel information, and then simultaneously output a set of log-likelihood values for the information bits. The outputs from the first decoder are used as inputs for the second iteration of the second decoder and vice versa.

FIG. 4 shows the difference between operating a turbo-code in serial 401 and parallel 402 modes for one iteration in each of the modes. In serial mode 401, the first decoder 411 operates first, and its output is used by the second decoder 412, and then the output from the second decoder is returned to be used by the first decoder in a next iteration. In parallel mode 402, the two decoders 421-422 operate in parallel, and the output of the first decoder is sent to the second decoder for the next iteration while simultaneously the output of the second decoder is sent to the first decoder.

Similarly to the case for turbo-codes, parallel-mode decoding for turbo product codes is described by C. Argon and S. McLaughlin, “A Parallel Decoder for Low Latency Decoding of Turbo product Codes,” IEEE Communications Letters, vol. 6, pp. 70-72, February 2002. In parallel-mode decoding of turbo product codes, the horizontal and vertical codes are decoded concurrently, and in the next iteration, the outputs of the horizontal codes are used as inputs for the vertical codes, and vice versa.

Group Shuffled Decoding

Finally, for BP decoding of LDPC codes, “group shuffled” BP decoding is described by J. Zhang and M. Fossorier, “Shuffled Belief Propagation Decoding,” Proceedings of the 36^{th} Annual Asilomar Conference on Signals, Systems, and Computers, pp. 8-15, November 2002.

In ordinary BP decoding, as described above, messages from all bits are updated in parallel in a single vertical step. In group-shuffled BP decoding, the bits are partitioned into groups. The messages from a group of bits to their corresponding constraints are updated together, and then, the messages from the next group of bits are updated, and so on, until the messages from all the groups are updated, and then the next iteration begins. The messages from constraints to bits are treated as dependent messages. At each stage, the latest updated messages are used. Group shuffled BP decoding improves the performance and convergence speed of decoders for LDPC codes compared to ordinary BP decoders.

Intuitively, the reason that the parallel-mode decoders for turbo-codes and turbo product codes, and the group-shuffled decoders for LDPC codes speed up convergence is as follows. Whenever a message is updated in an iterative decoder, it becomes more accurate and reliable. Therefore, using the most recent version of a message, rather than older versions, normally increases speed convergence to the correct decoding.

QC-LDPC Codes

Many LDPC codes have the disadvantage of requiring a significant amount of memory to store parity-check matrices. Another important disadvantage of many LDPC codes is that their parity check matrices are so random, that the wiring complexity involved in making a hardware decoder is prohibitive. These disadvantages make it difficult to implement LDPC decoders in hardware. For these reasons, quasi-cyclic LDPC (QC-LDPC) codes have been developed, R. M. Tanner, “A [155; 64; 20] sparse graph (LDPC) code,” IEEE International Symposium on Information Theory, Sorrento, Italy, June 2000, and US Patent Publications 20060109821, “Apparatus and method capable of a unified quasi-cyclic low-density parity-check structure for variable code rates and sizes,” and 20050149845 “Method of constructing QC-LDPC codes using q^{th}-order power residue.” Also see, U.S. Pat. No. 6,633,856 to Richardson et al. on Oct. 14, 2003, “Methods and apparatus for decoding LDPC codes,” incorporated herein by reference

The parity-check matrix of a QC-LDPC code includes circulant permutation sub-matrices or zero sub-matrices giving the code a QC property, which enables efficient high-speed very large scale integration (VLSI) implementations. For this reason a number of wireless communications standards use QC-LDPC codes, e.g., the IEEE 802.16e, 802.11n standards and DVB-S2 standards.

As shown below, quasi-cyclic LDPC codes have a parity-check matrix H of a special structured form, which makes them very convenient for hardware implementation. The parity check matrix is constructed out of square

z by z sub-matrices. These sub-matrices either consist of all zeroes, or they are permutation matrices. Permutation matrices are matrices with a single 1 in each row, where the column that the 1 is located is shifted from row to row. The following matrix is an example of a permutation matrix with z=6:

$${P}_{2} = ( \begin{matrix}0 & 0 & 1 & 0 & 0 & 0 \\ 0 & 0 & 0 & 1 & 0 & 0 \\ 0 & 0 & 0 & 0 & 1 & 0 \\ 0 & 0 & 0 & 0 & 0 & 1 \\ 1 & 0 & 0 & 0 & 0 & 0 \\ 0 & 1 & 0 & 0 & 0 & 0\end{matrix} ) .$$

This matrix is called “P₂” because when the rows and columns are counted starting with position 0, the first 1 in the 0^{th} row is in column 2. The permutation matrix P₀ is the identity matrix. If the value of the index t in Pₜ is greater than or equal to z, then the matrix just wraps around, so that for z=6, we have P₂=P₈=P₁₄, etc.

### SUMMARY OF THE INVENTION

A block of symbols are decoded using iterative belief propagation. A set of belief registers store beliefs that a corresponding symbol in the block has a certain value.

Check processors determine output check-to-bit messages from input bit-to-check messages by message-update rules. Link processors connect the set of belief registers to the check processors. Each link processor has an associated message register.

Messages and beliefs are passed between the set of belief registers and the check processors via the link processors for a predetermined number of iterations while updating the beliefs to decode the block of symbols based on the beliefs at termination.

### BRIEF DESCRIPTION OF THE DRAWINGS

FIG. 1 is a block diagram of prior art channel coding;

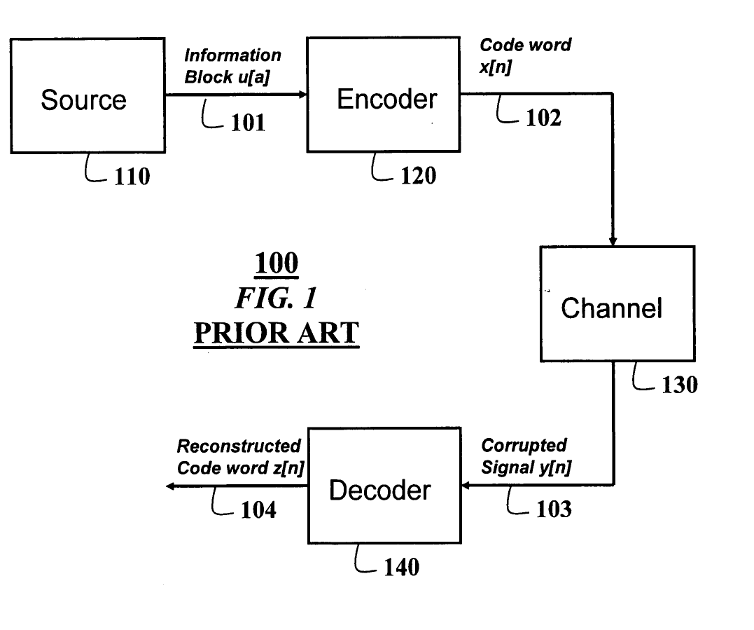

FIG. 2 is a block diagram of a prior art belief propagation decoding;

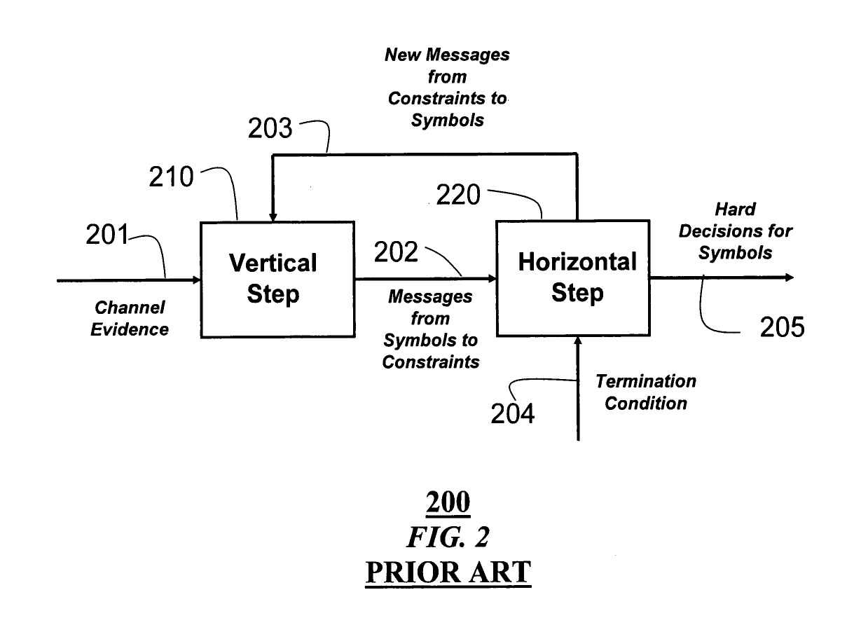

FIG. 3 is a schematic diagram of a prior art turbo-code.

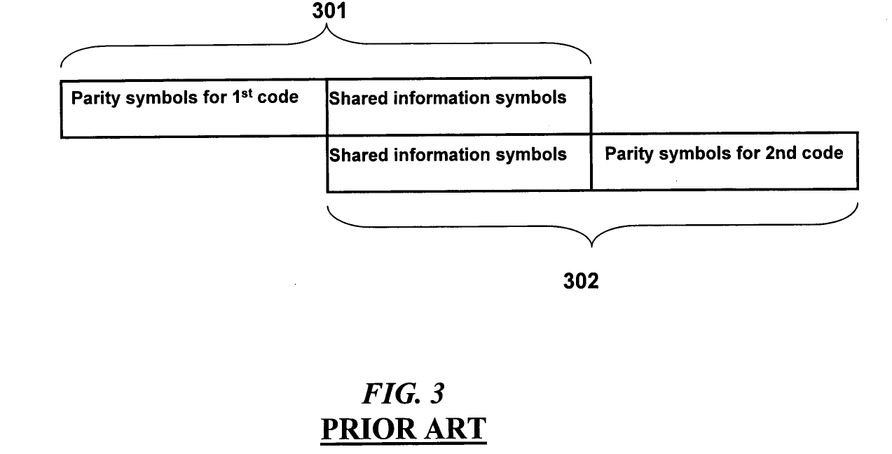

FIG. 4 is a block diagram of prior art serial and parallel turbo coding;

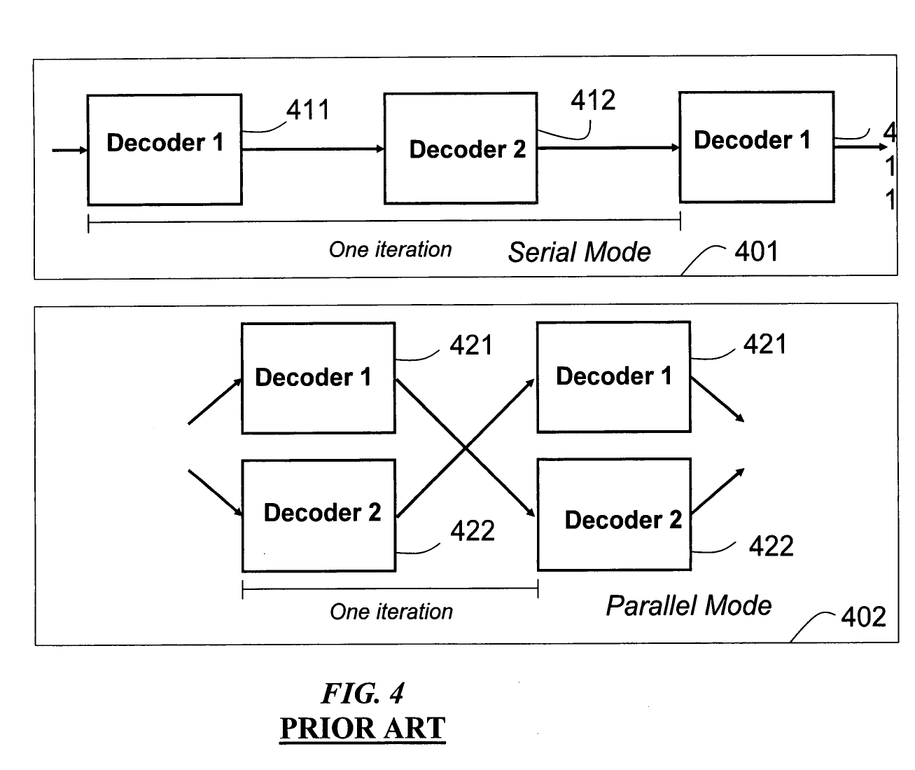

FIG. 5 is a flow diagram of a method for generating a combined-replica, group-shuffled, iterative decoder according to an embodiment of the invention;

FIG. 6 is a schematic diagram of replicated sub-decoders;

FIG. 7 is a diagram of a combined-replica, group-shuffled, iterative decoder according to an embodiment of the invention; and

FIG. 8 is a diagram of replicated sub-decoder schedules for a combined decoder for a turbo-code;

FIG. 9 is a base matrix according to an embodiment of the invention;

FIG. 10 is a factor graph according to an embodiment of the invention;

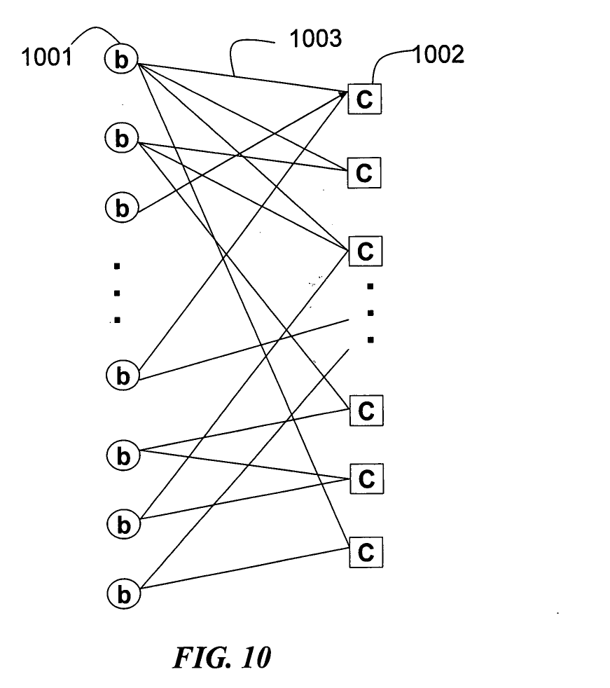

FIG. 11 is a block diagram a system and method for encoding and decoding data according to an embodiment of the invention;

FIG. 12 is a block diagram of a VLSI decoder according to an embodiment of the invention;

FIG. 13 is a block diagram of an architecture of the decoder of FIG. 12;

FIG. 14 is a block diagram of a belief register according to an embodiment of the invention;

FIG. 15A is a block diagram of a check processor according to an embodiment of the invention;

FIGS. 15B-15C are block diagrams of comparators used by the check processor of FIG. 15A;

FIG. 16 is a block diagrams of a link processor according to an embodiment of the invention;

FIG. 17 is a block diagram of a message register according to an embodiment of the invention; and

FIGS. 18A and 18B are block diagrams comparing conventional message updates with the message update according to an embodiment of the invention.

### DETAILED DESCRIPTION OF THE PREFERRED EMBODIMENT

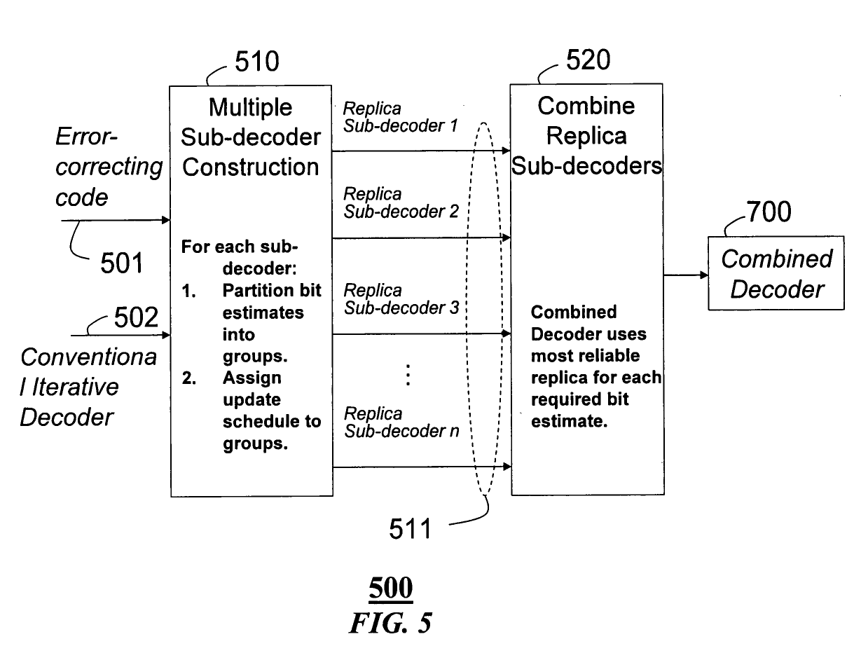

FIG. 5 shows a method for generating 500 a combined-replica, group-shuffled, iterative decoder 700 according to our invention.

The method takes as input an error-correcting code 501 and a conventional iterative decoder 502 for the error-correcting code 501. The conventional iterative decoder 502 iteratively and in parallel updates estimates of states of symbols defining the code based on previous estimates. The symbols can be binary or taken from an arbitrary alphabet. Messages in belief propagation (BP) methods and states of bits in bit-flipping (BF) decoders are examples of what we refer to generically as “symbol estimates” or simply “estimates” for the states of symbols.

We also use the terminology of “bit estimates” because for simplicity the symbols are assumed to be binary, unless stated otherwise. However the approach also applies to other non binary codes. Prior-art BP decoders, BF decoders, turbo-decoders, and decoders for turbo product codes are all examples of conventional iterative decoders that can be used with our invention.

To simplify this description, we use BF and BP decoders for binary LDPC codes as our primary examples of the input conventional iterative decoders 501. It should be understood that the method can be generalized to other examples of conventional iterative decoders, not necessarily binary.

In a BF decoder for a binary LDPC code, the estimates for the values of each code-word symbol are stored and updated directly. Starting with an initial estimate based on a most likely state given the channel output, each code-word bit is estimated as either 0 or 1. At every iteration, the estimates for each symbol are updated in parallel. The updates are made by checking how many parity checks associated with each bit are violated. If a number of checks that are violated is greater than some pre-defined threshold, then the estimate for that bit is updated from a 0 to a 1 or vice versa.

A BP decoder for a binary LDPC code functions similarly, except that instead of updating a single estimate for the value of each symbol, a set of “messages” between the symbols and the constraints in which the messages are involved are updated. These messages are typically stored as real numbers. The real numbers correspond to a log-likelihood ratio that a bit is a 0 or 1. In the BP decoder, the messages are iteratively updated according to message-update rules. The exact form of these rules is not important. The only important point is that the iterative decoder uses some set of rules to iteratively update its messages based on previously updated messages.

Constructing Multiple Sub-Decoders

In the first stage of the transformation process according to our method, multiple replicas of the group-shuffled sub-decoders are constructed. These group-shuffled sub-decoders 511 are then combined 520 into the combined-replica group-shuffled decoder 700.

Partitioning Estimates into Groups

The multiple replica sub-decoders 511 are constructed as follows. For each group-shuffled replica sub-decoder 511, the estimates that the group-shuffled sub-decoder makes for the messages or the symbol values are partitioned into groups.

An example BF decoder for a binary LDPC code has one thousand code-word bits. We can divide the bit estimates that the group-shuffled sub-decoder makes for this code in any number of ways, e.g., into ten groups of a hundred bits, or a hundred groups of ten bits, or twenty groups of fifty bits, and so forth. For the sake of simplicity, we assume hereafter that the groups are of equal size.

If the conventional iterative decoder 501 is a BP decoder of the LDPC code, the groups of messages can be partitioned in many different ways in each group-shuffled sub-decoder. We describe two preferred techniques. In the first technique, which we refer to as a “vertical partition,” the code-word symbols are first partitioned into groups, and then all messages from the same code-word symbol to the constraints are treated as belonging to the same group. In the vertical partition, the messages from constraints to symbols are treated as dependent messages, while the messages from the symbols to the constraints are treated as independent messages. Thus, all dependent messages are automatically updated whenever a group of independent messages from symbols to constraints are updated.

In the second technique, which we will refer to as a “horizontal partition,” the constraints are first partitioned into groups, and then all messages from the same constraint to the symbols are treated as belonging to the same group. In the horizontal partition, the messages from constraints to symbols are treated as the independent messages, and the messages from the symbols to the constraints are merely dependent messages. Again, all dependent messages are updated automatically whenever a group of independent messages are updated.

Other approaches for partitioning the BP messages are possible. The essential point is that for each replica of the group-shuffled sub-decoder, we define a set of independent messages that are updated in the course of the iterative decoding method, and divide the messages into some set of groups. Other dependent messages defined in terms of the independent messages are automatically updated whenever the updating of a group of independent messages completes.

Assigning Update Schedules to Groups

The next step in generating a single group-shuffled sub-decoder 511 assigns an update schedule for the groups of estimates. An update schedule is an ordering of the groups, which defines the order in which the estimates are updated. For example, if we want to assign an update schedule to ten groups of 100 bits in the BF decoder, we determine which group of bits is updated first, which group is updated second, and so on, until we reach the tenth group. We refer to the sub-steps of a single iteration when a group of bit estimates is updated together as a “iteration sub-step.”

The set of groups along with the update schedule for the groups, defines a particular group-shuffled iterative sub-decoder. Aside from the fact that the groups of estimates are updated in sub-steps according to the specified order, the group-shuffled, iterative sub-decoder functions similarly to the original conventional iterative decoder 501. For example, if the input conventional iterative decoder 501 is the BF decoder, then the new group-shuffled sub-decoder 511 uses identical bit-flipping rules as the conventional decoder 501.

Differences Between Replica Sub-Decoders Used in Combined Decoders

The multiple group-shuffled sub-decoders 511 may or may not be identical in terms of the way that the sub-decoders are partitioned into groups. However, the sub-decoders are different in terms of their update schedules. In fact, it is not necessary that every bit estimate is updated in every replica sub-decoder used in the combined decoder 700. However, every bit estimate is updated in at least one of the replica sub-decoders 511. We also prefer that each replica sub-decoder 511 has the same number of iteration sub-steps, so that each iteration of the combined decoder completes synchronously.

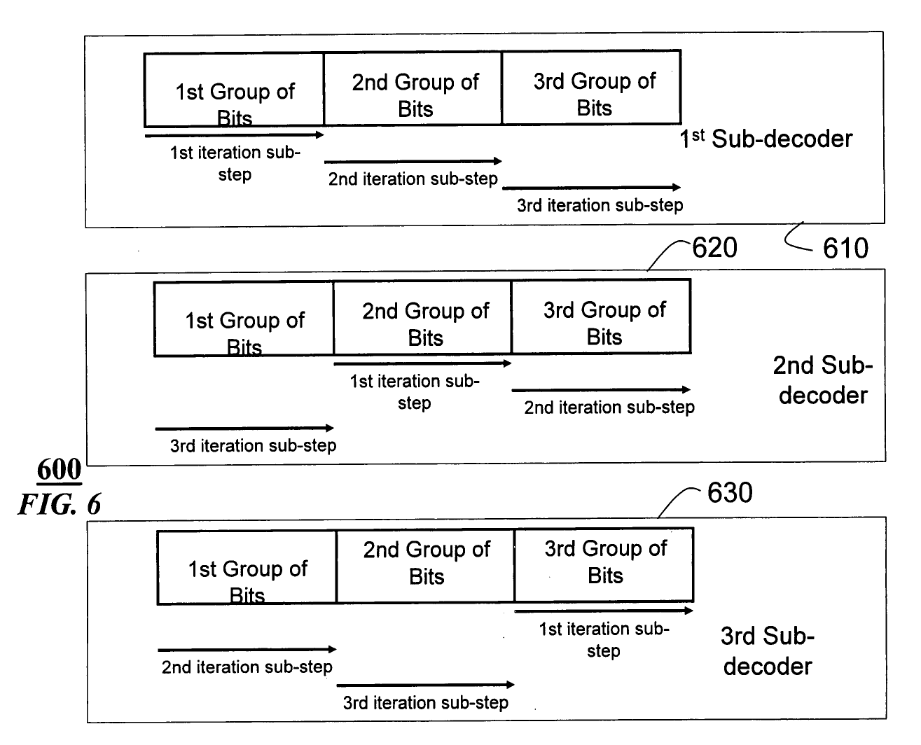

FIG. 6 shows a simple schematic example of replicated group-shuffled sub-decoders. In this example, we used three different replica sub-decoders, each having three groups of bit estimates. In this example, the groups used in each replica sub-decoder are identical, but the updating order is different.

In the first replica sub-decoder 610, the bit estimates in group 1 is updated in the first iteration sub-step, followed by the bit estimates in group 2 in the second iteration sub-step, followed by the bit estimates in group 3 in the third iteration sub-step. In the second replica sub-decoder 620, the bit estimates in group 2 are updated first, followed by the bit estimates in group 3, followed by the bit estimates in group 1. In the third replica sub-decoder 630, the bit estimates in group 3 are updated first, followed by the bit estimates in group 1, followed by the bit estimates in group 2.

The idea behind our combined-replica group-shuffled decoders is described using this example. Consider the first iteration, for which the input estimate for each bit is obtained using channel information. We expect that the initial input ‘reliability’ of each bit to be equal. However, after the first sub-step of the first iteration is complete, the bits that were most recently updated should be most reliable. Thus, in our example, we expect that for the first replica sub-decoder, the bit estimates in group 1 are the most reliable at the end of the first sub-step of the first iteration, while in the second replica sub-decoder, the bit estimates in group 2 are the most reliable at the end of the first sub-step of the first iteration.

In order to speed up the rate at which reliable information is propagated, it makes sense to use the most reliable estimates at each step. The general idea behind constructing a combined decoder from multiple replica group-shuffled sub-decoders is that we trade off greater complexity, e.g., logic circuits and memory, in exchange for an improvement in processing speed. In many applications, the speed at which the decoder functions is much more important than the complexity of the decoder, so this trade-off makes sense.

Combining Multiple Replica Sub-Decoders

The decoder 700 is a combination of the different replicas of group-shuffled sub-decoders 511 obtained in the previous step 510.

Whenever a bit estimate is updated in an iterative decoder, the updating rule uses other bit estimates. In the combined decoder, which uses the multiple replica sub-decoders, the bit estimates that are used at every iteration are selected to be the most reliable estimates, i.e., the most recently updated bit estimates.

Thus, to continue our example, if we combine the three replica sub-decoders described above, then the replica decoders update their bit estimates in the first iteration as follows. In the first sub-step of the first iteration, the first replica sub-decoder updates the bit estimates in group 1, the second replica sub-decoder updates the bit estimates in group 2, and the third replica sub-decoder updates the bit estimates in group 3.

After the first sub-step is complete, the replica sub-decoders update the second group of bit estimates. Thus, the first replica sub-decoder updates the bit estimates in group 2, the second replica sub-decoder updates the bit estimates in group 3, and the third replica sub-decoder updates the bit estimates in group 1.

The important point is that whenever a bit estimate is needed to do an update, the replica sub-decoder is provided with the estimate from the currently most reliable sub-decoder for that bit. Thus, during the second sub-step, whenever a bit estimate for a bit in group 1 is needed, the estimate is provided by the first replica sub-decoder, while whenever a bit estimate for a bit in group 2 is needed, this estimate is provided by the second replica sub-decoder.

After the second sub-step of the first iteration is complete, the roles of the different replica sub-decoders change. The first replica decoder is now the source for the most reliable bit estimates for bits in group 2, the second replica sub-decoder is now the source for the most reliable bit estimates for bits in group 3, and the third replica sub-decoder is now the source for the most reliable bit estimates for bits in group 1.

The general idea behind the way the replica decoders 511 are combined in the combined decoder 700 is that at each iteration, a particular replica sub-decoder “specializes” in giving reliable estimates for some of the bits and messages, while other replica sub-decoders specialize in giving reliable estimates for other bits and messages. The “specialist” replica decoder for a particular bit estimate is always that replica decoder which most recently updated its version of that bit estimate.

System Diagram for Generic Combined Decoder

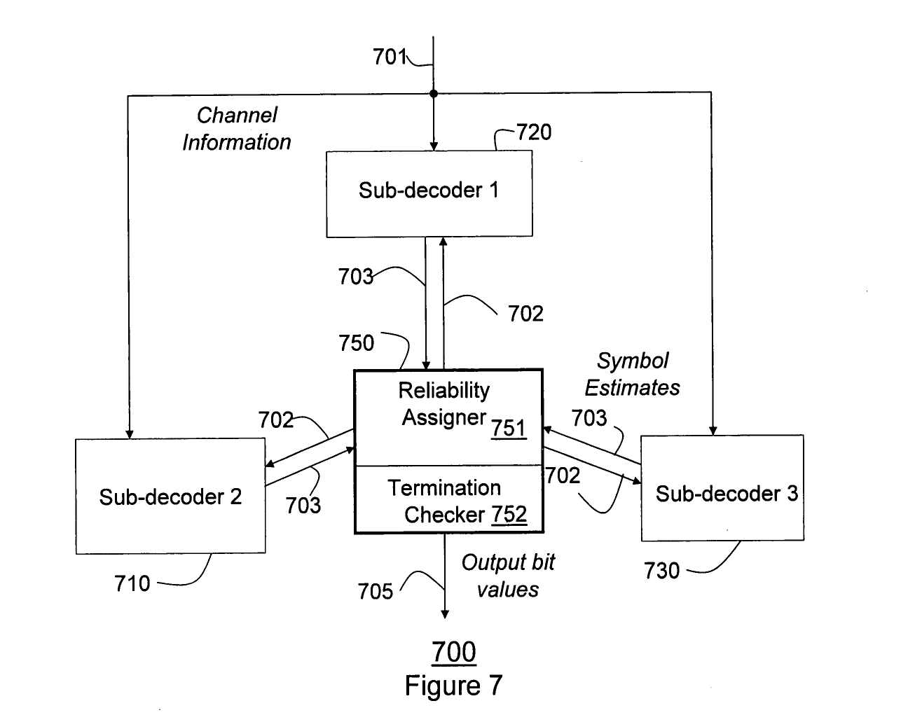

FIG. 7 shows a combined decoder 700. For simplicity, we show a combined decoder that uses three group-shuffled sub-decoders 710, 720, and 730. Each sub-decoder partitions estimates into a set of groups, and has a schedule by which the sub- it updates the estimates.

The overall control of the combined decoder is handled by a control block 750. The control block consists of two parts: reliability assigner 751; and a termination checker 752.

Each sub-decoder receives as input the channel information 701 and the latest bit estimates 702 from the control block 750. After each iteration sub-step, each sub-decoder outputs bit estimates 703 to the control block. To determine the output a particular sub-decoder applies the pre-assigned iterative decoder, e.g., BP or BF, using its particular schedule.

After each iteration sub-step, the control block receives as inputs the latest bit estimates 703 from each of the sub-decoders. Then, the reliability assigner 751 updates the particular bit estimates that the assigner has received to match the currently most reliable values. The assigner then transmits the most reliable bit estimates 702 to the sub-decoders.

The termination checker 752 determines whether the currently most reliable bit estimates correspond to a codeword of the error-correcting code, or whether another termination condition has been reached. In the preferred embodiment, the alternative termination condition is a pre-determined number of iterations. If the termination checker determines that the decoder should terminate, then the termination checker outputs a set of bit values 705 corresponding to a code-word, if a code-word was found, or otherwise outputs a set of bit values 705 determined using the most reliable bit estimates.

The description that we have given so far of our invention is general and applies to any conventional iterative decoder, including BP and BF decoders of LDPC codes, turbo-codes, and turbo product codes. Other codes to which the invention can be applied include irregular LDPC codes, repeat-accumulate codes, LT codes, and Raptor codes. We now focus on the special cases of turbo-codes and turbo product codes and quasi-cyclic LDPC (QC-LDPC) codes, in order to further describe details for these codes. For the case of QC-LDPC codes, we also provide details of the preferred hardware embodiment of the invention.

Combined Decoder for Turbo-Codes

To describe in more detail how the combined decoder can be generated for a turbo-code, we use as an example a turbo-code that is a concatenation of two binary systematic convolutional codes. We describe in detail a preferred implementation of the combined decoder for this example.

A conventional turbo decoder has two soft-input/soft-output convolutional BCJR decoders, which exchange reliability information, for the k information symbols that are shared by the two codes.

To generate the combined decoder for turbo-codes, we consider a parallel-mode turbo-decoder to be our input “conventional iterative decoder” 501. The relevant “bit estimates” are the log-likelihood ratios that the information bits receive from each of the convolutional codes. We refer to these log-likelihood ratios as “messages” from the codes to the bits.

In the preferred embodiment, we use four replica sub-decoders to generate the combined-replica group-shuffled decoder for turbo-codes constructed from two convolutional codes.

An ordering by which the messages are updated for each replica sub-decoder is assigned to each sub-coder. This can be done in many different ways, but it makes sense to follow the BCJR method, as closely as possible. In a conventional BCJR decoding “sweep” for a single convolutional code, each message is updated twice, once in a forward sweep and once in a backward sweep. The final output log-likelihood ratio output by the BCJR method for each bit is normally the message following the backward sweep. It is also possible to get equivalent results by updating the bits in a backward sweep followed by a forward sweep.

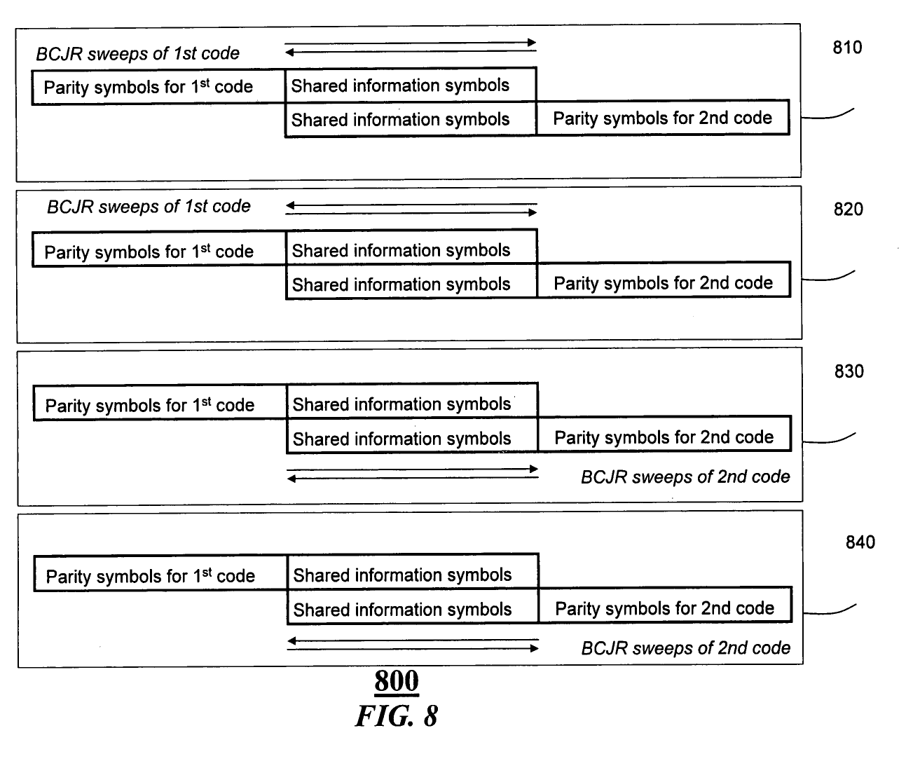

In our preferred embodiment, as shown in FIG. 8, the four replica sub-decoders are assigned the following updating schedules. In each replica sub-decoder, each single message is considered a group. The first replica sub-decoder 810 updates only the messages from the first convolutional code using the forward sweep of the schedule followed by a backward sweep of the schedule. The second replica sub-decoder 820 updates only the messages from the first convolutional code using a backward sweep followed by a forward sweep. The third replica sub-decoder 830 updates only the messages from the second convolutional code using a forward sweep followed by a backward sweep. The fourth replica sub-decoder 840 updates only the messages from the second convolutional code using a backward sweep followed by a forward sweep.

As each bit message is updated in each of the four replica sub-decoders, other messages are needed to perform the update. In the combined decoder, the message is obtained from that the replica sub-decoder which most recently updated the estimate.

Combined Decoder for Turbo Product Codes

We now describe the preferred embodiment of the invention for the case of turbo product codes (TPC). We assume that the turbo product code is constructed from a product of a horizontal code and a vertical code. Each code is decoded using a exact-symbol decoder. We assume that the exact-symbol decoders output log-likelihood ratios for each of their constituent bits.

To generate the combined decoder for turbo product codes, we consider a parallel-mode turbo product decoder to be our input “conventional iterative decoder” 501. The relevant “bit estimates” are the log-likelihood ratios output for each bit by the symbol-exact decoders for the horizontal and vertical sub-codes. We refer to these bit estimates as “messages.”

In the preferred embodiment, we use two replica sub-decoders that process successively the vertical codes and two replica sub-decoders that process successively the horizontal codes to generate the combined decoder for such a turbo product code. In the replica sub-decoders which successively process the vertical codes, the messages from those vertical codes are partitioned into groups such that messages from the bits in the same vertical code belong to the same group. In the replica sub-decoders which successively process the horizontal codes, the messages from the horizontal codes are partitioned into groups such that messages from the bits in the same horizontal code belong to the same group.

In the preferred embodiment for turbo product codes, the updating schedules for the different replica sub-decoders are as follows. In the first replica sub-decoder that processes vertical codes, the vertical codes are processed one after the other moving from left to right, while in the second replica sub-decoder that processes vertical codes, the vertical codes are processed one after the other moving from right to left. In the third replica sub-decoder that processes horizontal codes, the horizontal codes are processed one after the other moving from top to bottom. In the fourth replica sub-decoder that processes horizontal codes, the horizontal codes are processed one after the other moving from bottom to top.

At any stage, if a message is required, it is provided by the replica sub-decoder that most recently updated the message.

High-Speed Decoding of Quasi-Cyclic LDPC Codes

Quasi-cyclic low-density parity check (QC-LDPC) error-correcting codes have been accepted or proposed for a wide variety of communications standards, e.g., 802.16e, 802.11n, 3GPP, DVB-S2, and will likely be used in many future standards, because of their relatively good performance and convenient structure.

One embodiment of the invention provides a “replica-group-shuffled” decoder for QC-LDPC codes that have excellent performance vs. complexity trade-offs. The decoder can be implemented using VLSI circuits. A single overall architecture enables the decoding of QC-LDPC codes with different base matrices, different code rates, and different code lengths. The VLSI circuits can also support high-speed, or low-complexity (power) designs depending on the decoding application.

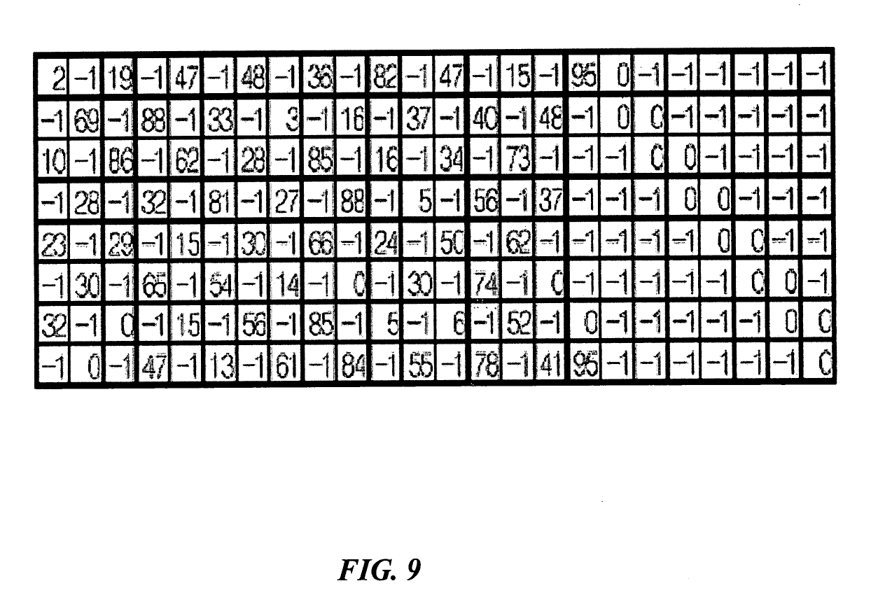

The parity check matrix H of a quasi-cyclic LDPC code is constructed using a “base matrix,” which specifies which sub-matrices to use. For example, one QC-LDPC code has a base matrix as shown in FIG. 9. This base matrix is used in the IEEE 802.16e standard.

This base matrix has 24 columns and 8 rows. The full parity check matrix H is obtained from the base matrix by replacing each −1 with a (z×z) all-zeros matrix, and replacing each other number t with the (z×z) permutation matrix Pₜ.

The IEEE 802.16e standard allows for many different possible values for z, ranging from z=24 to z=96. For the purposes of one implementation, we use the code shown in FIG. 9, with z=44, which means that for our code, N=24z=1056, and M=8z=352, i.e., each block has 1056 bits or information symbols, and 352 check bits.

Encoding and Decoding

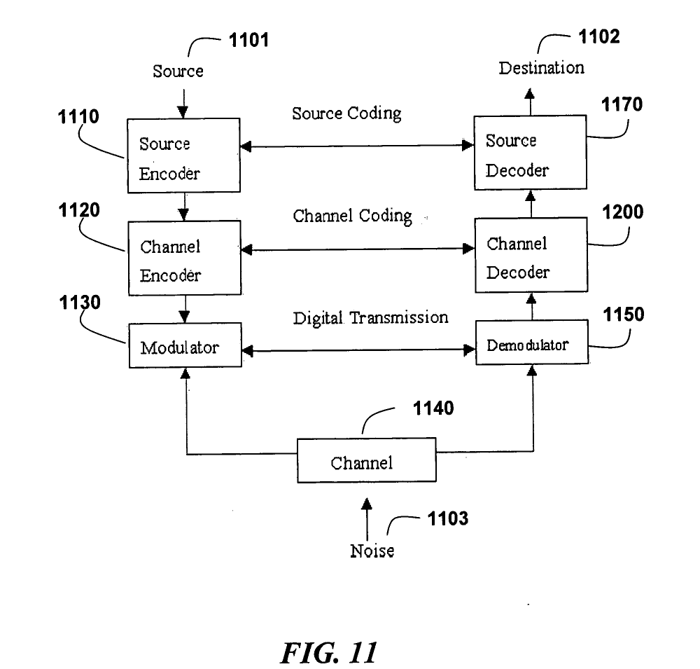

FIG. 11 shows the overall structure of a system for coding a block of information symbols according to an embodiment of the invention. A source encoder encodes 1110 binary input data, which are than channel encoded 1120, and modulated 1130. The encoded and modulated data are passed through channel 1140 with additive noise 1103 as an analog signal. At a destination 1102, a received noisy signal is demodulated 1150, channel decoded 1200, and passed to a source decoder 1160 to recover the input data.

When the analog received signals are de-modulated, they are converted into a number that expresses a ‘belief’ that each received bit is a zero or a one. This initial belief for a bit is also called the “channel information.” The belief can be considered a probability that the bit is a zero, ranging from 0 to 1.0. For example, if the value of the belief is 0.0001, the signal is probably a one, and a value of 0.9999 would tend to indicate a logical 0. A value of 0.5123 could be either a zero or a one. It should be noted that the values can be in other ranges, e.g., negative and positive. In the preferred embodiment, the probability is expressed as a log-likelihood ratio (LLR), which is stored using a small number of bits. A positive LLR indicates that the bit is probably a zero, while a negative LLR indicates that the bit is probably a one.

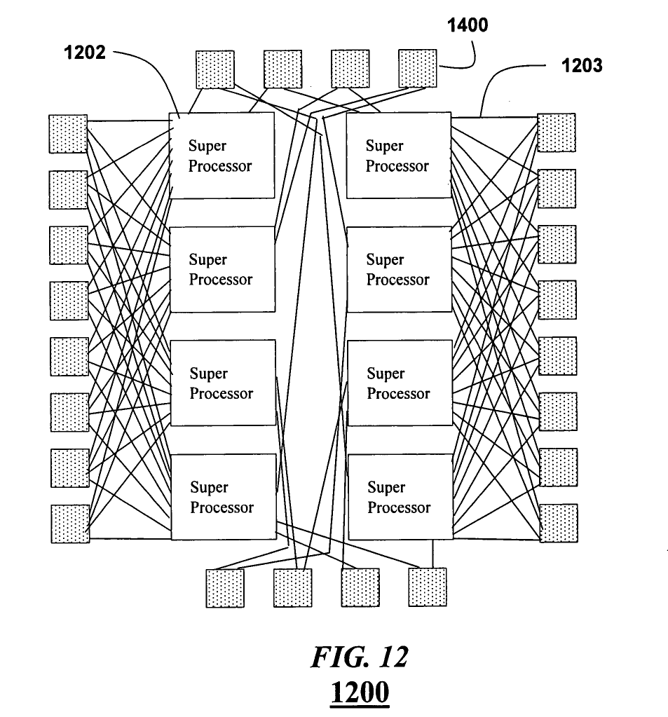

It is the purpose of the decoder, shown in FIG. 12, to return a code-word that is highly probable given the received channel information. The beliefs are collected into groups of size z, and a group of beliefs is stored in a bank of registers 1400. The set of banks of registers are coupled to a relatively small number, e.g., 8, of “super-processors” 1202 by wires 1203. The way that the wires are connected is determined by the particular base-matrix of the QC-LDPC error correcting code that is used. Each super-processor includes a single “check processor” and a number of link processors.

Horizontal Group-Shuffled Min-Sum Decoder

As described above, in a conventional “horizontal shuffled” decoder, we cycle through the check nodes one by one, updating bit-to-check messages and beliefs automatically as one cycles through the check nodes. As also described above, in a “horizontal group-shuffled” decoder, we organize the check nodes into groups, and update the different groups serially while the checks within a group are processed. That is, all the check-to-bit messages for each check node are determined in parallel.

The way we apply this idea to decoding quasi-cyclic LDPC codes is by forming z groups of M/z checks, where z is the size of the permutation matrices in the parity check matrix, and M/z is the number of rows in the base matrix of the code. For example, for the code from the IEEE 802.16e standard, with the base matrix shown in FIG. 9, and with z=44, we have 44 groups, each of 8 check bits for total of 352 check bits.

In our architecture as shown in FIG. 12, we devote one super processor 1202 to each of the checks in a group. Therefore as shown in FIG. 12, we use eight super processors 1202, which work in parallel, stepping through the 44 groups.

Each super processor includes one check processor connected to a number of link processors. For the 802.16e code, that number is ten link processors for all but one of the super-processors, and eleven link processors for the last one. Generally, the number of link processors connected to a particular check processor is the number of non “−1” entries in a row of the base matrix. There is one check processor for each row in the base matrix. The link processors are then connected to banks of belief registers 1400, such that only one link processor can update a particular belief register at the time

Replicated Horizontal Group-Shuffled Min-Sum Decoder

We can also “replicate” the check processors 1500. As described, each check processor steps through 44 checks in order. We can replicate these processors by having, for example one processor stepping through the 44 checks in the order 1, 2, 3, . . . , 43, 44, while a second processor steps through the checks in the order 23, 24, 25, . . . 43, 44, 1, 2, . . . , 21, 22, etc. Of course, many other possible orders exist.

The belief for each of the bits is stored in a single belief register. Therefore, we carefully select the order that each check processor uses to step through the checks, in order to avoid any conflicts caused by two check processors simultaneously accessing the same belief register of memory as the processors update the bit beliefs.

Replicating check processors adds additional complexity to the decoder. Replicating reduces the number of iterations necessary to achieve a certain performance, which can be advantageous for some applications.

Decoder Architecture

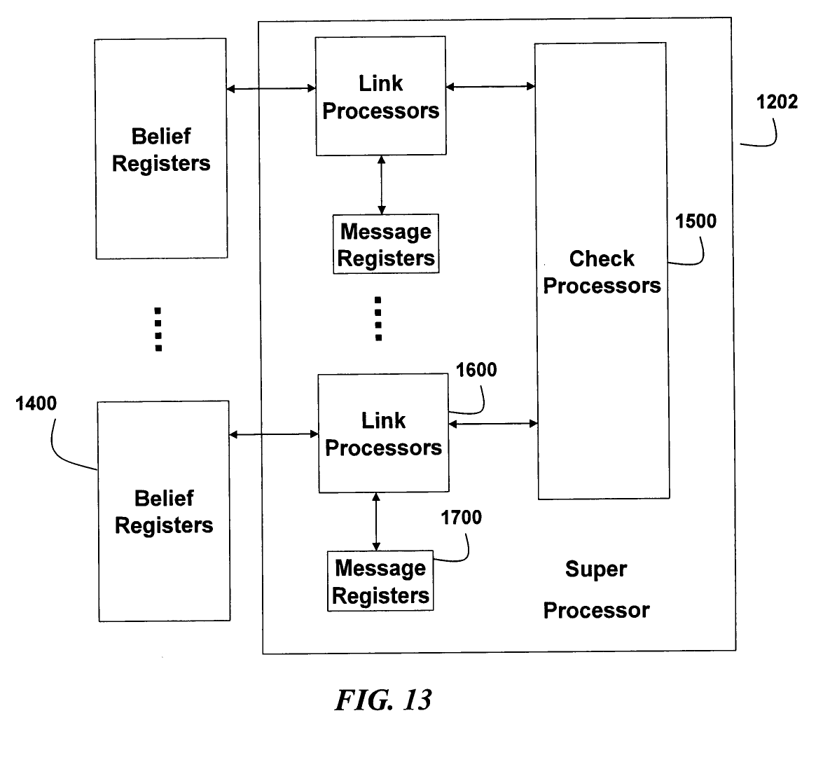

FIG. 13 show an architecture of our decoder in a greater detail. Each super processor 1202 contains a check processor 1500 and a set of (e.g., ten) link processors 1600. Each super-processor is connected to a set of (e.g., ten) banks of belief registers 1400 via the link processors. The number of link processors in each super-processor is determined by the number of non-zero sub-matrices in the row corresponding to the super-processor associated with the base matrix.

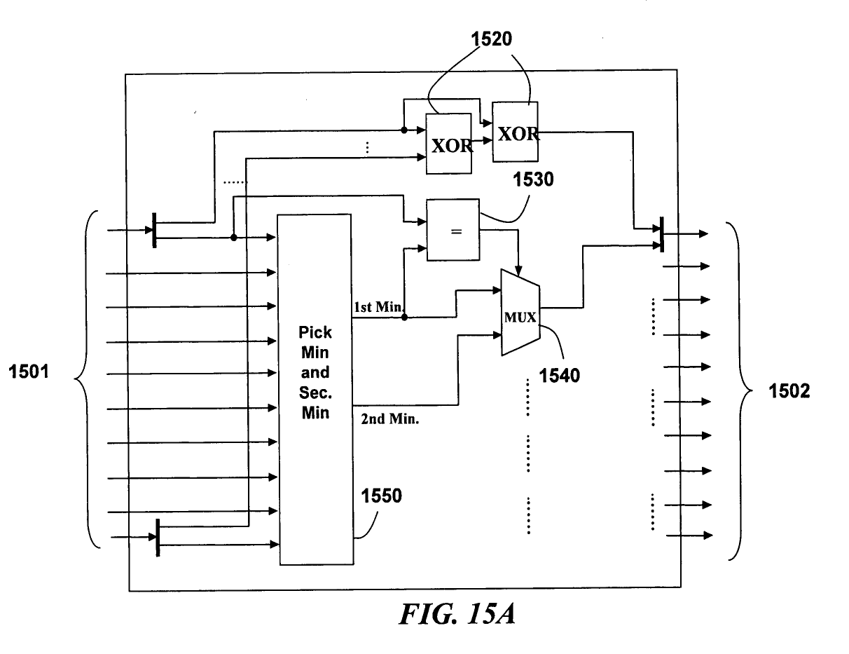

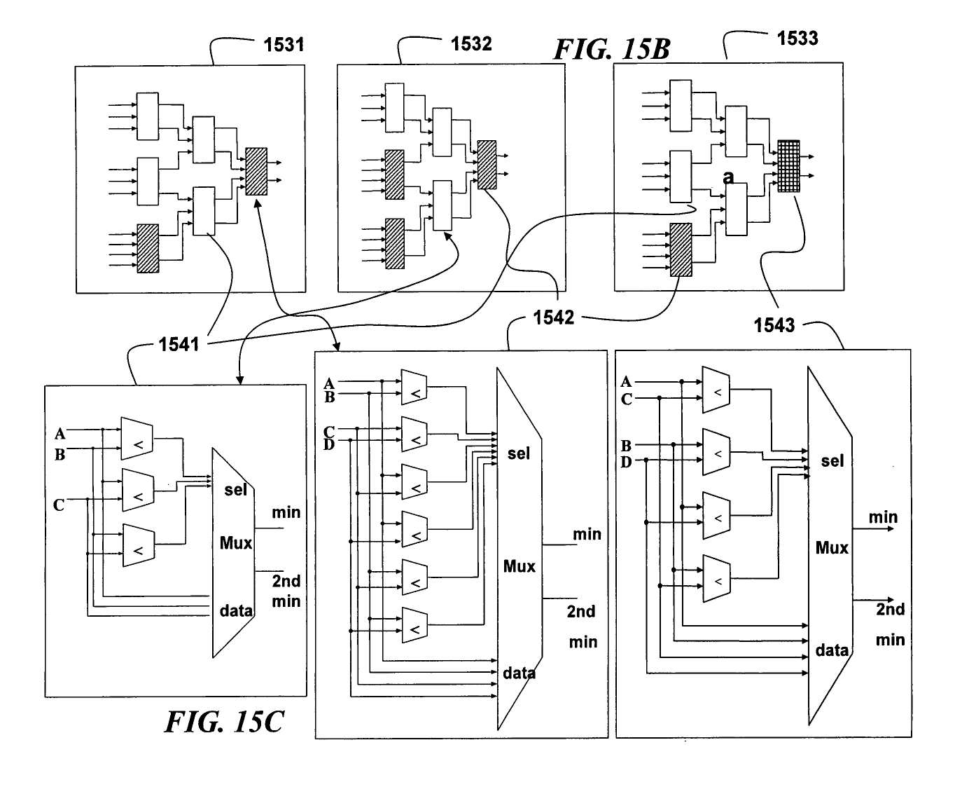

Each link processor 1600 has an associated message register 1700. This architecture is much simpler than the prior art Richarchson architecture shown in U.S. Pat. No. 6,633,856 to Richardson FIGS. 15-17.

During operation, the belief registers 1400 are initialized with the beliefs produced by the demodulator 1250. The decoder 1200 operates on the beliefs for a predetermined number of iterations. During each iteration, beliefs and messages are passed back and forth between the belief registers and the check processors 1500 via the link processors 1600. The messages are stored in message registers 1700.

The link processors enforce that the beliefs stay within a predetermined range of values, e.g., that the values do not underflow or overflow the register size. In a preferred embodiment, the message registers 1700 store only check-to-bit messages. The memory can be stored in shift registers as generally described below. When the decoding terminates, the final beliefs can be read from belief registers and thresholded to recover the input data.

It should be noted, that the architecture does not include bit processors as might be found in prior art decoders. Also, processors are associated with the links themselves.

Belief Registers

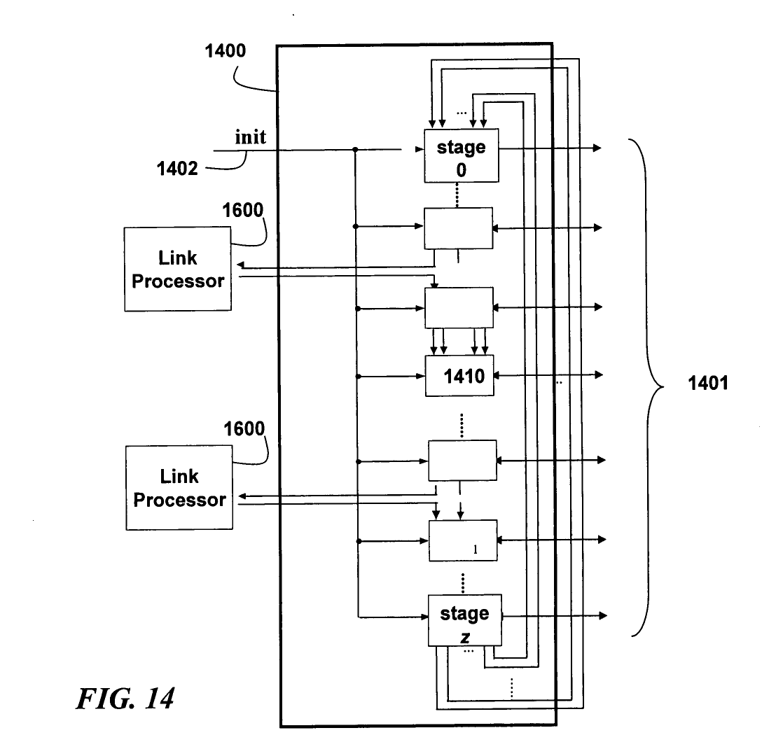

FIG. 14 shows a structure a bank of belief registers in greater detail. The set of belief registers are grouped to form multiple banks of belief registers. Each bank of belief registers 1400 is associated with one column in the base matrix of the code, see FIG. 9. Each bank of belief registers stores the beliefs corresponding to variable nodes (bits) in the corresponding base matrix column. Line 1402 is used to initialize the register.

Instead of storing the beliefs statically, and accessing the beliefs as required, in this embodiment of the invention, we store the beliefs in shift registers, and the values automatically cycle from one stage to another, until the values are sent to the appropriate super-processor. This design exploits the fact the quasi-cyclic structure of the LDPC code.

A bank of belief register contains z stages (individual belief registers) 1410, where z is the dimension of permutation matrices. As can be seen, the stages are shifted in a circular manner so that each stage either passes its belief to the next stage or outputs its belief to the connected link processor 1600. The input for a stage is either the belief coming from the previous stage or the updated belief from the connected link node processor. The init signal 1402 forces all the stages to load the channel information from the demodulator 1150 of a new block to be decoded.

It should be noted that only selected stages are connected to the link processors. The placement of the connections to the link processors mostly depends on the base matrix used. Thus, if a certain super-processor is connected to a given bank of belief registers, and the base matrix has a permutation matrix of Pₜ for that connection, then normally one would connect the t^{th} stage to the super-processor. However, it is important that there is an additional degree of freedom that can be exploited. One can choose, for a particular super-processor, to always connect to stage t+k instead of stage t. As long as one does that consistently for every connection coming out of a super-processor, the decoder will still operate correctly. This degree of freedom, which we call the “shift degree of freedom” is exploited to ensure that two super-processors do not simultaneously access the same belief register. In hardware implementations, it is sometimes useful for detailed timing reasons to avoid having two connections to super-processors appear in adjacent stages. We can also optimize the shift degree of freedom to also avoid this situation.

Check Processor

FIG. 15A shows the check processor 1500. The check processor has ten inputs 1501 and ten outputs 1502, one from each associated link processor, see FIG. 13. Each of the inputs comes from a different link processor, and each of the outputs goes to a different link processor. The check processor receives inputs corresponding to belief-to-check messages, and it computes output messages corresponding to check-to-bit messages. Note that the check-to-bit messages are stored in message registers 1700, but the bit-to-check messages are not stored, and are instead computed as necessary.

The check processor implements a belief propagation message update rule. In the embodiment described here, the check processor updates according to the min-sum rule described above and below using XOR gates, comparator gates, and MUX blocks shown in FIGS. 15A-15C.

The min-sum message-update rules are defined as follows. Each message is given a time index, and new messages are iteratively determined from old messages using the message-update rules. The message update rules are as follows:

$$Initialization \text{:} {U}_{m \to n}^{( 0 )} = 0 , \\ Bit node update \text{:} {V}_{n \to m}^{( t + 1 )} \text{:} = {I}_{n} + {\sum }_{{m}^{′} ∈ N ( m ) \backslash m} {U}_{{m}^{′} \to n}^{( t )} , \\ Check node update : {U}_{m \to n}^{( t )} := {min}_{{n}^{′} ∈ N ( m ) \backslash n} \vert {V}_{{n}^{′} \to m}^{( t )} \vert {\prod }_{{n}^{′} ∈ N ( m ) \backslash n}^{ } sgn ( {V}_{{n}^{′} \to m}^{( t )} ) , \\ and$$

$$Belief update \text{:} {B}_{n}^{t} = {I}_{n} + {\sum }_{m ∈ M ( n )} {U}_{m \to n}^{( t )} ,$$

where U_{m→n} is the message from check m to bit n, V_{n→m} is the message from bit n to check m, and Bₙ is the belief for bit n. The superscripts are used to indicate the time index. Note that M(n) is the set of all check nodes connected to bit node n, and vice-versa for N(m), and M(n)/m is defined as the set of all check nodes connected to bit nodes n except for check node m.

Other message updating rules, e.g., the sum-product rules, or the normalized min-sum rules, differ in comparison with the min-sum rules in the details of the message-update rules. Implementing these different message-update rules entails complexity/performance trade-offs. The trade-off do not require large changes in the over-all architecture of the system. Typically, the message-update decoding process terminates after some pre-determined number of iterations. At that point, each bit is assigned to be a zero when its (positive) belief is greater than or equal to zero, and a one otherwise, if its belief is negative.

Each message has a sign and a magnitude. For the magnitude, using the min-sum message update rule, the check processor determines a minimum message, and sends the message to all link processors, except for the one from which the link processor received the minimum message. Instead, that link receives the second best minimum value.

The sign of each outgoing check-to-bit message is determined by the number of incoming bit-to-check messages that “believe” that they are more likely to be one, and thus have a negative LLR. If that number is odd, then the outgoing message should have a negative LLR, while if that number is even, then the outgoing message should have a positive LLR.

Therefore, we determine 1550 first and second minimums for output messages. The magnitude of each input message is compared 1530 with the first minimum value. If it is equal to the first minimum value, the second minimum value is selected 1540, using a MUX, as the magnitude of the corresponding output message. Otherwise, the first minimum value becomes the magnitude of the corresponding output message.

For the sign, because a likely bit value of 0 corresponds to a positive LLR and a likely bit value of 1 corresponds to a negative LLR, the product of the signs corresponds to the XOR of the values. The sign of the output is the product of the signs of all the inputs excluding that of its corresponding input. We use two XOR blocks 1520 to fulfill this function as shown in FIG. 15A. Then, the magnitude of each output is combined with its corresponding sign, which generates the complete output message.

As shown in FIG. 15B, the comparator 1530 is actually constructed as a cascade of comparators. Three variations 1531, 1532 and 1532 are shown.

For a 10-input comparison, the input messages are divided into three groups, with 3, 3, and 4 messages, respectively. A block comparator 1641 receives three inputs and compares each pair among them. Thus, there are three parallel comparisons and according to the comparison results, it outputs the minimum value and the second minimum value. The shaded block comparator 1542 receives four inputs and compares each pair. So there are six parallel comparisons and according to the comparison results, it outputs the minimum value and the second minimum value.

In the cascade 1533, we use a comparator 1543. Because we know the ordering of the outputs of comparator 1541 in the second stage, we do not need to compare these again in the third stage.

Link Processor

At any time during the message updating process, the message U_{m→n} from a check node m to a bit node n, the message V_{n→m} from a bit node n to a check node m, and the belief Bₙ at a bit node n are connected by an equation

V_{n→m}=Bₙ−U_{m→n}.

This equation is useful for our embodiments, because the equation means that we only need to store the beliefs and the check-to-bit messages, and determine bit-to-check messages from the stored information as needed, see FIG. 13. This property also holds for other message updating processes, such as the sum-product process, and the normalized min-sum process, because the property only depends on the bit-node update and the belief update equations, which are unchanged in other processes, in comparison with the min-sum process.

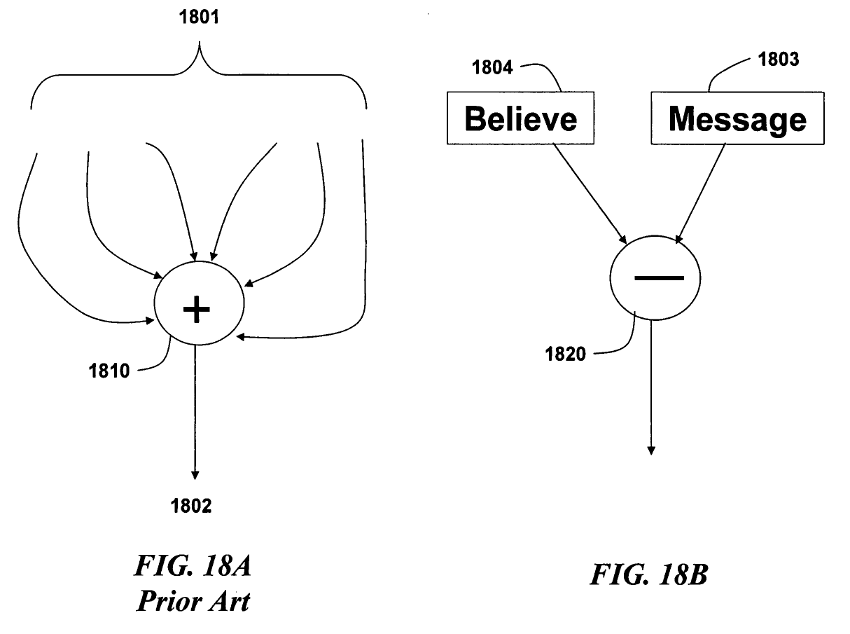

FIGS. 18A and 18B contrast the conventional message update with the update with the update according to the embodiments of the invention. In the prior art, the check-to-bit messages 1801 are summed at a bit-processor 1810 to produce the output bit-to-check messages 1802 for. Instead, to compute the bit-to-check-messages, we subtract 1820 the check-to-bit messages from the beliefs.

Because we use this approach, we do not need to use bit-processors, and we do not need to store bit-to-check messages. Instead, we use link processors, which only need to access a single check-to-bit message and a single belief.

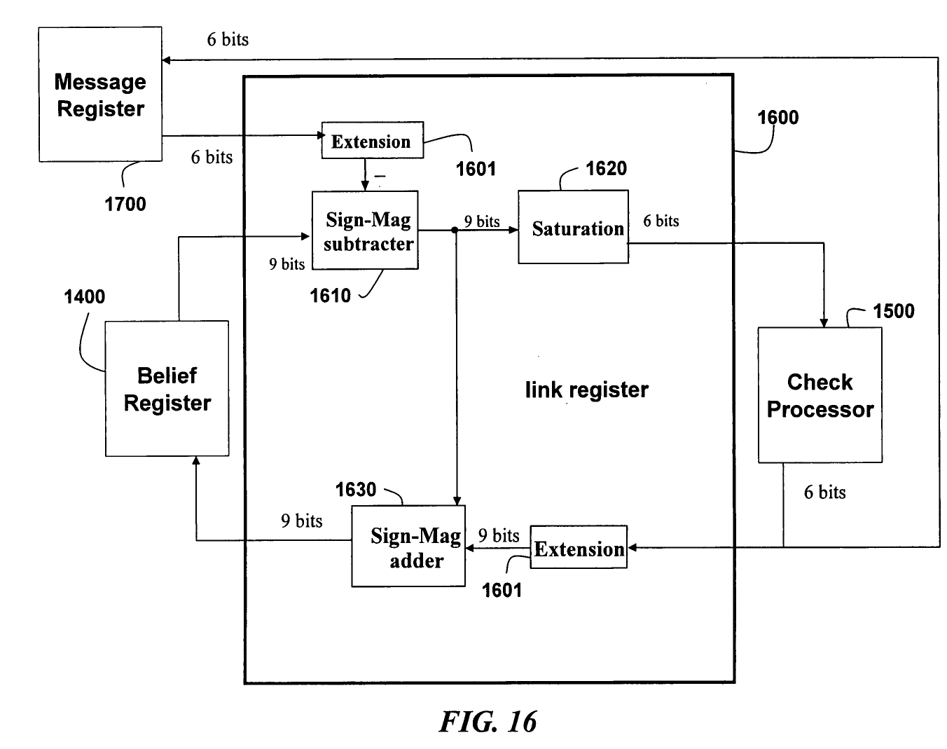

FIG. 16 shows the link processor 1600 for messages between the belief registers and the check processors. As shown in FIG. 16, the link processor takes inputs from a belief register 1400 and a message register 1700. In the embodiment shown, the beliefs are stored as 9-bit LLR values (one bit for the sign, the remaining 8 bits for the magnitude), while the check-to-bit messages are stored as 6-bit LLR values. After subtracting 1610 the message from the belief, and limiting the maximum value of the magnitude of the remainder to a 5 bit value, using the saturation block 1620, we send the resulting value to the corresponding check processor. To recover the beliefs from the check-to-bit messages sent by the check processor, we perform an addition operation 1630.

Message Register

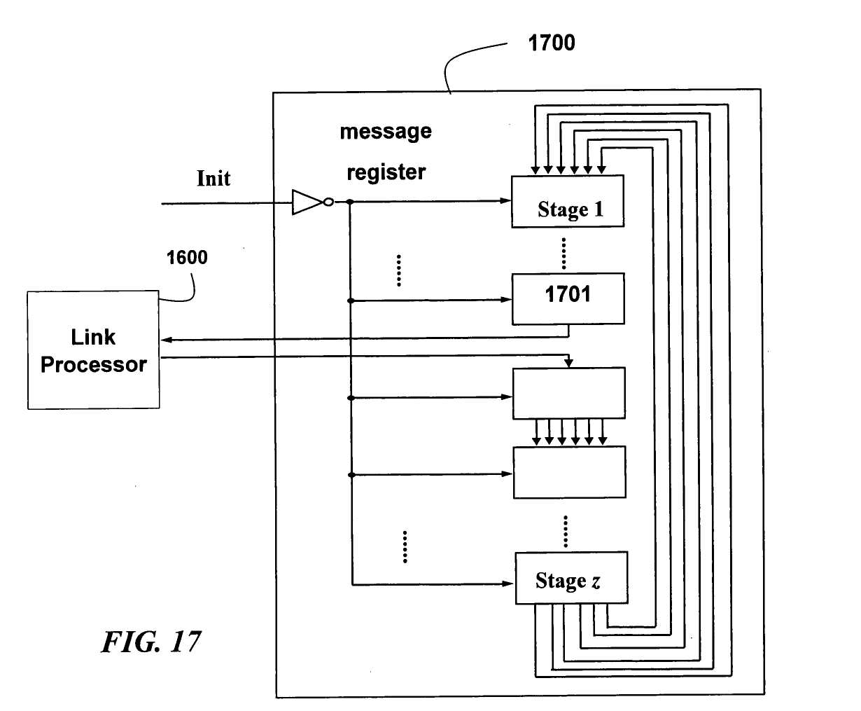

As shown in FIG. 17, in one embodiment of the invention, the structure of the message registers 1700 is uses shift registers similar to those previously described for the belief registers. Each message register is associated with a non-zero entry in the base matrix of the code.

The message register includes z stages, where z is the dimension of the permutation matrices. Each stage either passes its message to the next stage or outputs its message to a connected link processor. The input is either the message coming from the previous stage or the updated message from the connected link processor. The signal init is a synchronous reset that forces all the stages to output all zeroes at a rising edge when the signal is ‘1’. The init signal is set to ‘1’ at the beginning of decoding each block, and set to ‘0’ after one clock cycle because messages need to be initialized as all zeroes.

### Effect of the Invention

Simulations with the combined decoder according to the invention show that the combined decoder provides better performance, complexity and speed trade-offs than prior art decoders. The replica shuffled turbo decoder invention outperforms conventional turbo decoders by several tenths of a dB if the same number of iterations are used, or can use far fewer iterations, if the same performance at a given noise level is required.

Similar performance improvements result when using the invention with LDPC codes, or with turbo-product codes, or any iteratively decodable code.

Although the invention has been described by way of examples of preferred embodiments, it is to be understood that various other adaptations and modifications may be made within the spirit and scope of the invention. Therefore, it is the object of the appended claims to cover all such variations and modifications as come within the true spirit and scope of the invention.

1. An apparatus for decoding a block of symbols using iterative belief propagation, comprising:
a set of belief registers, each belief register configured to store a belief that a corresponding symbol in the block has a certain value;
a plurality of check processors, the plurality of check processors configured to determine output check-to-bit messages from input bit-to-check messages by message-update rules;
a plurality of link processors connecting the set of belief registers to the plurality of check processors; and
means for passing the check-to-bit and bit-to-check messages and the beliefs between the set of belief registers and the plurality of check processors via the link processors for a predetermined number of iterations while updating the beliefs.

2. The apparatus of claim 1, in which the link processors determine output bit-to-check messages using input beliefs and the check-to-bit messages.

3. The apparatus of claim 1, in which each link processor has an associated message register, the message register storing only the check-to-bit messages.

4. The apparatus of claim 1, in which the block of symbols is encoded using a quasi-cyclic low density parity code (QC-LDPC) having a base matrix of m rows and n columns, in which there is one column for every bank of belief registers, and one row for each check processor.

5. The apparatus of claim 4, in which the base matrix includes z permutation sub-matrices, and each bank of belief registers includes z belief stages, each belief stage corresponding to a single belief register.

6. The apparatus of claim 5, in which the values of the beliefs are circulated through the belief stages of each bank of belief registers, and an input for a particular belief stage is either the belief coming from a previous belief stage or an updated belief from a connected link processor.

7. The apparatus of claim 1, in which the updating is according to a min-sum process.

8. The apparatus of claim 1, in which the updating is according to a sum-product process.

9. The apparatus of claim 1, in which the updating is according to a normalized min-sum process.

10. The apparatus of claim 1, in which the link processor subtracts the check-to-bit message from the belief of the connected belief register to produce the bit-to-check message.

11. The apparatus of claim 5, in which each message register includes z message stages.

12. The apparatus of claim 11, in which the values of the message registers are circulated through the message stages of each message register during the updating.

13. The apparatus of claim 1, in which the set of belief registers is partitioned into a plurality of banks of belief registers, and in which the link processors and the check processors are arranged in a set of super processors such that there is one check register and a plurality of link registers in each super processor.

14. The apparatus of claim 13, in which the block of symbols is encoded using a quasi-cyclic low density parity code (QC-LDPC) having a base matrix of m rows and n columns, in which there is one super processor for each row, and in which there is one column for every bank of belief registers, and one row for each check processor, and a number of link processors in each super-processor is determined by a number of non-zero sub-matrices in the row corresponding to the super-processor.

15. The apparatus of claim 14, in which the link processors are connected to the banks of belief registers, such that only one link processor updates a particular belief register at any one time.

16. The apparatus of claim 15, in which a shift degree of freedom is used to avoid connecting two adjacent belief registers to the same super-processor.

17. A method for decoding a block of symbols using iterative belief propagation, comprising:
storing a belief that a particular symbol in the block has a certain value in an associated belief registers;
determining, in associated check processors and according to message-update rules, output check-to-bit messages from input bit-to-check messages received from the belief registers; and
passing the messages and beliefs between the belief registers and the check processors via the link processors for a predetermined number of iterations while updating the beliefs.
